(19) United States
(12) Patent Application Publication
(10) Pub. No.: US 2016/0372641 A1
(43) Pub. Date: Dec. 22, 2016

(54) POLYCARBOSILOXANE CONTAINING CURABLE COMPOSITIONS FOR LED ENCAPSULANTS

(71) Applicant: Henkel AG & Co.KGaA, Duesseldorf (DE)

(72) Inventors: Wentao Xing, Shanghai (CN); Liwei Zhang, Shanghai (CN); Juan Du, Shanghai (CN); Karen Leyssens, Berchem (BE); Yong Zhang, Shanghai (CN)

(21) Appl. No.: 15/251,664

(22) Filed: Aug. 30, 2016

Related U.S. Application Data
(63) Continuation of application No. PCT/CN2014/076444, filed on Apr. 29, 2014.

(51) Int. Cl. H01L 33/56; C08G 77/08; C08G 77/00

(52) U.S. Cl. CPC H01L 33/56; C08G 77/80; C08G 77/08; C08G 2190/00; H01L 2933/005

(57) ABSTRACT

The present invention relates to curable compositions comprising specific silicon-containing polymers, at least one vinyl carbosiloxane polymer, and at least a catalyst, cured products obtainable by heating such composition, and the use of said composition as semiconductor encapsulating material and/or electronic elements packaging material. More particularly, the invention relates to hydrosilylation-curable compositions that cure to form polycarbosiloxane products having optical clarity, resistance to high temperature, and very good moisture and gas barrier properties. This invention further relates to reliable light emitting devices encapsulated with these polycarbosiloxane compositions.

### FIELD OF THE INVENTION

The present invention relates to curable compositions comprising specific silicon-containing polymers, at least one vinyl carbosiloxane polymer, and at least a catalyst, cured products obtainable by heating such composition, and the use of said composition as semiconductor encapsulating material and/or electronic elements packaging material. More particularly, the invention relates to hydrosilylation-curable compositions that cure to form polycarbosiloxane products having optical clarity, resistance to high temperature, and very good moisture and gas barrier properties. The composition is useful in manufacturing reliable light emitting devices encapsulated with these polycarbosiloxane compositions.

### BACKGROUND

For light emitting device such as a light emitting diode (LED) and a photo coupler, a composition for sealing a light emitting element is required to have high thermal stability and UV stability.

As such a sealing composition, for example, epoxy resin and the like have been conventionally used. However, recently LEDs have become more and more efficient resulting in increased luminance, increased heat generation during use and emission of light of shorter wavelength, and thus the use of the epoxy resin has been a cause of cracking and yellowing.

Therefore, an organopolysiloxane component (silicone composition) has been used as a sealing composition, which is excellent in heat resistance and ultraviolet resistance. Methyl type of silicone composition is firstly introduced to the market because of the good thermal stability at high temperature, but it was replaced by phenyl type of silicone gradually since phenyl silicone has better barrier property. However, phenyl silicone shows worse thermal stability in some critical application, such as high power and high brightness LEDs as phenyl silicone shows quick decrease in transmittance above 150° C. Thus, it is a challenge to develop an LED encapsulant based on phenyl silicone with improved thermal stability.

This invention provides a silicone composition with improved thermal stability. This composition must comprise vinyl carbosiloxane (VCSR), serving as a thermal stabilizer. Preferably, the vinyl carbosiloxane (VCSR) is a polymer comprising some vinyl D4 moieties, which decrease the reactivity of platinum. Thus, such moieties can improve the thermal stability and at the same time will not result in the weight loss problem because of the polymer property.

The term D4 is known to those skilled in the art and refers to the following structure:

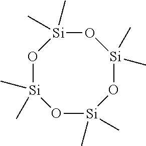

“Vinyl D4” refers to the following structure:

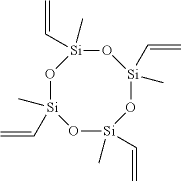 [SMILES: C=C[Si]1(C)O[Si](C)(C=C)O[Si](C)(C=C)O[Si](C)(C=C)O1]

A polymer comprising vinyl D4 moieties is a polymer that comprises moieties resulting from reacting vinyl D4 with monomers, oligomers and/or polymers comprising a functional group that is able to chemically react with the vinyl groups of vinyl D4.

Many references deal with such silicone compositions and their use for LED manufacturing.

WO 2009154261 A1 describes a curable organopolysiloxane composition comprising: (A) a branched-chain organopolysiloxane that contains in one molecule at least three alkenyl groups and at least 30 mole % of all silicon-bonded organic groups in the form of aryl groups; (B) a linear-chain organopolysiloxane that contains aryl groups and has both molecular terminals capped with diorganohydrogen-siloxy groups; (C) a branched-chain organopolysiloxane that contains in one molecule at least three diorganohydrogensiloxy groups and at least 15 mole % of all silicon-bonded organic groups in the form of aryl groups; and (D) a hydrosilylation catalyst. The composition is capable of forming a cured body that has a high index of refraction and strong adhesion to substrates. The thermal stability is not good enough in high power LED applications.

EP 1904579 B1 discloses a curable organopolysiloxane resin composition having a viscosity at 25° C. in the range of 0.001 to 5,000 Pa·s, a total acid number as specified by JIS K 2501 (1992) in the range of 0.0001 to 0.2 mg/g, and light transmittance in a cured state equal to or greater than 80%; as well as an optical part comprised of a cured body of the aforementioned composition. The curable organopolysiloxane resin composition of the invention is characterized by good transparency, low decrease in transmittance when exposed to high temperatures, and excellent adhesion when required. It was found that quick decrease in transmittance was observed in critical situation such as 200° C.

U.S. Pat. No. 6,806,509 B2 describes a potting composition comprising (A) an organopolysiloxane having a vinyl group at an end of its molecular chain, (B) an organohydrogenpolysiloxane, (C) a platinum group metal catalyst, and optionally, (D) an organosilicon compound having a silicon atom-bonded alkoxy group. The cured product of the composition has a refractive index of 1.41-1.56 at 25° C. and 589 nm (sodium D line). The composition is suited for the embedment and protection of light-emitting semiconductor members. A package in which a light-emitting semiconductor member is embedded and protected with the potting composition undergoes little discoloration and maintains a high emission efficiency in heating tests, thus offering a light-emitting semiconductor device featuring a long life and energy saving. The thermal stability is not good enough in high power LED applications.

WO 2012002561 A1 discloses a curable organopolysiloxane composition that can be used as a sealant or a bonding agent for optical semiconductor elements and comprises at least the following components: (A) an alkenyl-containing organopolysiloxane that comprises constituent (A-1) of an average compositional formula and constituent (A-2) of an average compositional formula; (B) an organopolysiloxane that contains silicon-bonded hydrogen atoms and comprises constituent (B-1) containing at least 0.5 wt. % of silicon-bonded hydrogen atoms and represented by an average molecular formula, constituent (B-2) containing at least 0.5 wt. % of silicon-bonded hydrogen atoms and represented by an average compositional formula, and, if necessary, constituent (B-3) of an average molecular formula; and (C) a hydrosilylation-reaction catalyst. The composition can form a cured body that possesses long-lasting properties of light transmittance and bondability, and relatively low hardness. The thermal stability is not good enough in high power LED applications.

WO 2008023537 A1 describes a curable organopolysiloxane composition comprising at least the following components: (A) a linear diorganopolysiloxane with a mass average molecular weight of at least 3000, (B) a branched organopolysiloxane, (C) an organopolysiloxane having, on average, at least two silicon-bonded aryl groups and, on average, at least two silicon-bonded hydrogen atoms in one molecule, and (D) a hydrosilylation reaction catalyst; has excellent curability and, when cured, forms a flexible cured product of high refractive index, optical transmissivity, excellent adherence to various substrates, high hardness and slight surface tack. The thermal stability is not good enough in high power LED applications.

From the above documents, it can be seen that silicone compositions are widely used as LED encapsulant material.

However, it is still a challenge to develop an LED encapsulant based on phenyl silicone with improved thermal stability.

### SUMMARY OF THE INVENTION

The object of the invention is to provide an LED encapsulant based on phenyl silicone, which is curable via hydrosilylation and after curing exhibits high transparency, heat stability, and very good gas and moisture barrier properties. Another object is to provide a cured product obtainable by heating a curable composition.

The invention relates to a curable composition, comprising:

(A) at least one organopolysiloxane A represented by the following formula (1):

[R¹R²R³SiO_{1/2}]_{M}[R⁴R⁵SiO_{2/2}]_{D}[R⁶SiO_{3/2}]_{T}[SiO_{4/2}]_{Q},

wherein R¹, R², R³, R⁴, R⁵, and R⁶, each independently designates a methyl group, an ethyl group, a vinyl group, a phenyl group, with the proviso that each molecule comprises at least 2 vinyl groups directly bonded to silicon; and M, D, T, and Q each represents a number ranging from 0 to less than 1, provided that M+D+T+Q is 1, and
(B) at least one organopolysiloxane B represented by the following formula (2):

[R⁷R⁸R⁹SiO_{1/2}]_{M′}[R¹⁰R¹¹SiO_{2/2}]_{D′}[R¹²SiO_{3/2}]_{T′}[SiO_{4/2}]_{Q′}, (2),

wherein R⁷, R⁸, R⁹, R¹⁰, R¹¹, and R¹², each independently designates a methyl group, an ethyl group, a phenyl group, or hydrogen, with the proviso that each molecule comprises at least 2 phenyl groups and 2 hydrogen atoms directly bonded to silicon, and M′, D′, T′, and Q′ each represents a number ranging from 0 to less than 1, provided that M′+D′+T′+Q′ is 1,
(C) at least one vinyl carbosiloxane polymer comprising the structures

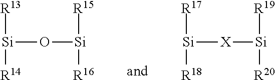

within each molecule, wherein R¹³, R¹⁴, R¹⁵, R¹⁶ R¹⁷, R¹⁸ R¹⁹, and R²⁰ each independently designates a methyl group, an ethyl group, a vinyl group, or a phenyl group, with the proviso that each molecule comprises at least 2 vinyl groups and at least one phenyl group directly bonded to silicon, and X is ethylene or arylene, and
(D) at least a catalyst

Furthermore, the present invention relates to a cured polycarbosiloxane composition obtainable by heating a polycarbosiloxane composition according to the present invention, as well as to the use of a polycarbosiloxane composition according to the present invention as semiconductor encapsulating material and/or electronic elements packaging material.

### DETAILED DESCRIPTION

The curable composition according to the invention comprises:

(A) at least one organopolysiloxane A
(B) at least one organopolysiloxane B
(C) at least one vinyl carbosiloxane polymer, and
(D) at least a catalyst.

A “curable composition” is understood to be a mixture of two or more substances which mixture can be converted from a soft state into a harder state by means of physical or chemical actions. Those physical or chemical actions can consist, for example, in the delivery of energy in the form of heat, light, or other electromagnetic radiation, but also in simply bringing into contact with atmospheric moisture, water, or a reactive component. Preferably, the composition of the present invention is heat-curable.

The curable composition according to the invention comprises organopolysiloxane A represented by formula (1), and organopolysiloxane B represented by formula (2) as described above. In both cases the polymer, i.e. the organopolysiloxane, comprises different “units”, wherein a unit is understood to be a structural motive which is formed of 1 silicon-atom and—according to the number of valencies at the silicon-atom—4 bridging groups X and remaining groups R, respectively, being directly bonded to the silicon-atom. A unit having only one bridging group X may also be called mono-functional or M-unit. A unit having two bridging groups may be called di-functional or D-unit, a unit having three bridging groups tri-functional or a T-unit, and a unit having four bridging groups tetra-functional or a Q-unit. The number of specific units being present in a particular polymer is represented by the indices M and M′, D and D′, T and T′, and Q and Q′.

The curable composition of the invention comprises at least an organopolysiloxane A, which is represented by the following formula (1):

[R¹R²R³SiO_{1/2}]_{M}[R⁴R⁵SiO_{2/2}]_{D}[R⁶SiO_{3/2}]_{T}[SiO_{4/2}]_{Q},

wherein R¹, R², R³, R⁴, R⁵, and R⁶, each independently designates a methyl group, an ethyl group, a vinyl group, a phenyl group, with the proviso that each molecule comprises at least 2 vinyl groups directly bonded to silicon; and M, D, T, and Q each represents a number ranging from 0 to less than 1, provided that M+D+T+Q is 1.

Preferably, the organopolysiloxane A is represented by the formula (1), wherein M is greater than 0.

It is preferred that the weight average molecular weight of the organopolysiloxane A is from 300 g/mol to 300,000 g/mol, preferably from 1000 g/mol to 100,000 g/mol. If reference is made herein to a weight average molecular weight, this reference refers to the weight average molecular weight Mw determined by gel permeation chromatography (GPC) according to DIN 55672-1:2007-08 with THF as the eluent.

Their viscosity is preferably 0.001-5000 Pa·s at 25° C. and more preferably 0.01-1000 Pa·s at 25° C. (Brookfield DV-+Digital Viscometer/LV, (spindle S64, rotation speed 50 rpm)).

The curable composition of the invention further comprises at least an organopolysiloxane B, which is represented by the following formula (2):

[R⁷R⁸R⁹SiO_{1/2}]_{M′}[R¹⁰R¹¹SiO_{2/2}]_{D′}[R¹²SiO_{3/2}]_{T′}[SiO_{4/2}]_{Q′}, (2),

wherein R⁷, R⁸, R⁹, R¹⁰, R¹¹, and R¹², each independently designates a methyl group, an ethyl group, a phenyl group, or hydrogen, with the proviso that each molecule comprises at least 2 phenyl groups and 2 hydrogen atoms directly bonded to silicon, and M′, D′, T′, and Q′ each represents a number ranging from 0 to less than 1, provided that M′+D′+T′+Q′ is 1.

Preferably, the organopolysiloxane B is represented by the formula (2), wherein M′ is greater than 0.

It is preferred that the weight average molecular weight of the organopolysiloxane B is from 500 g/mol to 300,000 g/mol, preferably from 600 g/mol to 100,000 g/mol. Their viscosity is preferably 0.001-5000 Pa·s at 25° C. and more preferably 0.002-1000 Pa·s at 25° C. (Brookfield DV-+Digital Viscometer/LV, (spindle S64, rotation speed 50 rpm)).

The curable composition of the invention further comprises at least a vinyl carbosiloxane polymer. The vinyl carbosiloxane polymer comprises the structures

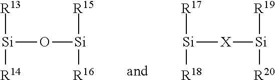

within each molecule, wherein R¹³, R¹⁴, R¹⁵, R¹⁶ R¹⁷, R¹⁸ R¹⁹, and R²⁰ each independently designates a methyl group, an ethyl group, a vinyl group, or a phenyl group, with the proviso that each molecule comprises at least 2 vinyl groups and at least one phenyl group directly bonded to silicon, and X is ethylene or arylene.

The vinyl carbosiloxane polymer is preferably the hydrosilylation reaction product of 1,3,5,7-tetravinyl-1,3,5,7-tetramethylcyclotetrasiloxane and at least one hydride-terminated linear polysiloxane, siloxane, carbosilane or silane, having two terminal Si—H hydrogens reactive with vinyl groups in a hydrosilylation reaction, wherein at least one of the hydride-terminated linear polysiloxanes, siloxanes, carbosilanes or silanes comprises at least one aryl and/or arylene group, preferably a phenyl group directly bonded to a silicon atom.

Preferably, the hydride-terminated linear polysiloxane, siloxane, carbosilane or silane, having two terminal Si—H hydrogens reactive with vinyl groups in a hydrosilylation reaction is selected from those having the structures:

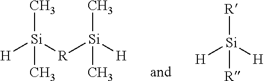

wherein R is a arylene group, preferably a phenylene group, or a linear silicone unit of the structure —(O—SiAr₂)—ₙ or —(O—SiMeAr)—ₙ, in which n is an integer from 1 to 1000 and represents the number of repeating units; Me is a methyl group; Ar is an aryl group, preferably a phenyl group; and R′ and R″ independently are a C1 to C4 alkyl group or an aryl group with the proviso that at least one of R′ and R″ is phenyl.

The hydrosilylation reaction of one or more of the vinyl groups of 1,3,5,7-tetravinyl-1,3,5,7-tetramethylcyclotetrasiloxane with a Si—H hydrogen of the hydride-terminated linear polysiloxane, siloxane, carbosilane or silane is preferably performed under Pt catalysis at 70-150° C. for 1-10 hours.

It is preferred that the weight average molecular weight of the vinyl carbosiloxane polymer is from 500 to 100,000 g/mol, preferably from 1500 to 50,000 g/mol.

Preferably, the curable composition according to the invention comprises the organopolysiloxane A, organopolysiloxane B and the vinyl carbosiloxane polymer in respective amounts to provide a molar Si—H/Si-Vinyl ratio of from 0.5 to 10, preferably from 0.6 to 5. If more than one, e.g. two, three, four or five different organopolysiloxanes A, organopolysiloxanes B and/or vinyl carbosiloxane polymers are present, the given ratio refers to the total amount of all such compounds being present.

The curable composition furthermore comprises at least a catalyst. It may contain just one catalyst, but also a combination of more than one, e.g. 2, 3, 4, or 5 catalysts. As catalyst any compound may be used which is able to promote the hydrosilylation addition reaction between vinyl and/or allyl groups in components (A) and (C) and Si—H groups in component (B). Typical addition reaction catalysts are platinum group metal catalysts including platinum catalysts, such as the reaction products of chloroplatinic acid with monohydric alcohols, complexes of chloroplatinic acid with olefins, and platinum bisacetoacetate, as well as palladium catalysts and rhodium catalysts.

Preferably, the catalyst is one or more compound selected from the group consisting of platinum group metal catalysts.

There are no special restrictions with regard to the amount of the catalyst used, provided that it is added in a catalytic amount sufficient for accelerating the desired hydrosilylation reaction. The addition reaction catalyst preferably is used in such an amount to give about 1 to 500 ppm (parts per million by weight), especially about 2 to 100 ppm of metal, especially of platinum group metal, based on the total weight of the curable composition. The term “metal” or “platinum group metal”, respectively, only refers to the content of the metal itself, even if in the curable composition the metal is present as a complex compound.

The curable composition of the invention may be prepared by simply mixing all ingredients. A thus prepared mixture is ready to be applied and to be cured, e.g. by applying heat.

However, in one embodiment of the invention the composition is a two-component preparation consisting of component 1 and component 2, wherein component 1 comprises organopolysiloxane A and the total amount of catalyst being present and component 2 comprises the total amount of organopolysiloxane B being present and optionally further organopolysiloxane A. The vinyl carbosiloxane polymer may be added to component 1, component 2 or both components. Each component may be filled in a different container, e.g. a tube or jar, or a different compartment of a two-compartment container, e.g. a two-chamber tube. This allows safely storing the composition without causing premature curing. Component 1 and component 2 are kept separately until application. To apply the composition, component 1 and component 2 are mixed and the mixture is applied to the desired place.

In addition to the components (A) to (D) described above, the composition according to the present invention may further comprise optional components insofar as the objects of the invention are not compromised.

Possible optional components include addition reaction inhibitors for adjusting curing time and imparting a pot life, and adhesion promoters to improve the adhesive properties of the composition.

Suitable reaction inhibitors include ethynylcyclohexanol, 2-methyl-3-butyn-2-ol, 3,5-dimethyl-1-hexyn-3-ol, 2-phenyl-3-butyn-2-ol, or similar alkyne alcohols; 3-methyl-3-penten-1-yne, 3,5-dimethyl-3-hexen-1-yne, or a similar enyne compound; 1,3,5,7-tetramethyl-1,3,5,7-tetravinyl-cyclotetrasiloxane, 1,3,5,7-tetramethyl-1,3,5,7-tetrahexenyl-cyclotetrasiloxane, benzotriazole, or the like. There are no special restrictions with regard to the quantities in which these inhibitors can be added but it may be recommended that in terms of weight units these inhibitors be added in a quantity of 10 to 1,000 ppm per weight of the composition.

An adhesion promoter is understood to mean a substance that improves the adhesion properties of the composition on surfaces. Conventional adhesion promoters (tackifiers) known to the person skilled in the art can be used individually or as a combination of several compounds. Suitable examples include resins, terpene oligomers, coumarone/indene resins, aliphatic petrochemical resins and modified phenolic resins. Suitable within the framework of the present invention are, for example, hydrocarbon resins, as obtained by polymerization of terpenes, mainly a- or P-pinene, dipentene or limonene. Polymerization of these monomers is usually cationic with initiation using Friedel-Crafts catalysts. The terpene resins also include copolymers of terpenes and other monomers, such as styrene, a-methylstyrene, isoprene and the like. The above-mentioned resins are used, for example, as adhesion promoters for pressure-sensitive adhesives and coating materials. Also suitable are the terpene phenolic resins, which are produced by acid-catalyzed addition of phenols to terpenes or rosin. Terpene phenolic resins are soluble in most organic solvents and oils and miscible with other resins, waxes and rubber. Also suitable as adhesion promoters within the framework of the present invention in the above sense are the rosins and their derivatives, such as esters or alcohols thereof. Particularly suitable are silane adhesion promoters, in particular aminosilanes and epoxysilanes, for example 3,4-epoxycyclohexylethyl trimethoxysilane.

Suitable fillers for the composition according to the invention are, for example, chalk, lime powder, precipitated and/or pyrogenic silica, zeolites, bentonites, magnesium carbonate, kieselguhr, alumina, clay, talc, titanium oxide, iron oxide, zinc oxide, sand, quartz, flint, mica, glass powder and other ground minerals. In addition, organic fillers, especially carbon black, graphite, wood fibers, wood flour, sawdust, wood pulp, cotton, pulp, wood chips, chopped straw, chaff, ground walnut shells and other chopped fibers, can also be used. Furthermore, short fibers such as glass fiber, glass filament, polyacrylonitrile, carbon fiber, Kevlar fiber or polyethylene fibers can also be added. Aluminum powder is also suitable as filler. In addition, hollow spheres with a mineral shell or a plastic shell are suitable as fillers. These can be, for example, hollow glass spheres, which are commercially available with the trade names Glass Bubbles®. Hollow spheres based on plastics are available for example under the trade names Expancel® or Dualite®. These are composed of inorganic or organic substances, each having a diameter of 1 mm or less, preferably of 500 μm or less. For some applications, fillers which impart thixotropy to the preparations are preferred. Such fillers are also described as rheological auxiliaries, e.g. hydrogenated castor oil, fatty acid amides or swellable plastics such as PVC. So that they can be pressed out readily from a suitable metering device (e.g. tube), such preparations have a viscosity of 3,000 to 15,000, preferably 4,000 to 8,000 mPas or 5,000 to 6,000 mPas.

The fillers may be used in a quantity of 1 to 80 wt.-%, based on the total weight of the composition. A single filler or a combination of several fillers can be used.

In the event that a basic filler is to be used instead of acidic fillers, for example calcium carbonates (chalks) are suitable, in which case cubic, non-cubic, amorphous and other modifications can be used. Preferably, the chalks used are surface treated or coated. As a coating agent, preferably fatty acids, fatty acid soaps and fatty acid esters are used, for example lauric acid, palmitic acid or stearic acid, sodium or potassium salts of such acids or their alkyl esters. In addition, however, other surface-active substances, such as sulfate esters of long-chain alcohols or alkylbenzenesulfonic acids or their sodium or potassium salts or coupling reagents based on silanes or titanates, are also suitable. The surface treatment of chalks is often associated with an improvement in processability and adhesive strength and the weathering resistance of the compositions. The coating composition is usually used in a proportion of 0.1 to 20 wt.-%, preferably 1 to 5 wt.-%, based on the total weight of the crude chalk.

Depending on the desired property profile, precipitated or ground chalks can be used. Ground chalks can be produced, for example, from natural lime, limestone or marble by mechanical grinding, using either dry or wet methods. Depending on the grinding process, fractions having different average particle sizes can be obtained. Advantageous specific surface area values (BET) are between 1.5 m²/g and 50 m²/g.

If desired, phosphor and antidegradants may also be added.

Further auxiliary substances and additives include plasticizers, stabilizers, antioxidants, reactive diluents, drying agents, UV stabilizers, anti-ageing agents, rheological auxiliaries, fungicides and/or flame retardants.

Curing of the compositions according to the invention typically involves heating at 50 to 200° C., and particularly at 50 to 160° C., for 0.1 to 5 hours, and particularly for 0.2 to 4 hours. Furthermore, post-curing may also be conducted at 50 to 200° C., and particularly at 70 to 160° C., for 0.1 to 10 hours, and particularly for 1 to 6 hours.

Furthermore, the invention relates to cured products obtainable by heating a curable composition according to the invention.

A further subject matter of the present invention is the use of a curable polycarbosiloxane composition according to the invention in encapsulation, sealing, protection, bonding and/or lens formation materials, in particular as semiconductor encapsulating material and/or electronic elements packaging material. The polycarbosiloxane composition of the invention can provide enhanced barrier properties against moisture and gases. In particular, the polycarbosiloxane composition according to the invention is advantageously used in encapsulation materials for the encapsulation of semiconductor devices, especially of light emitting devices (LEDs).

### EXAMPLES

As follows is a description of particular aspects of the present invention using a series of examples, however, the present invention is in no way restricted to the below presented examples.

Test Methods:

The evaluations were conducted in the manner described below.

In the following examples, weight average molecular weight values are polystyrene-equivalent values measured using gel permeation chromatography (GPC).
Vinyl content was titrated according to Chinese Chemical Industry Standard HG/T 3312-2000.
Hydrogen content was titrated as disclosed in Feng S. Y.; Zhang, J.; Li, M. J.; Zhu, Q. Z.; Organosilicon Polymer and Application Thereof, p. 400-401; Chemical Industry Press.
Hardness was measured with a LX-A Shore durometer.
Transmittance was measured by an UV-Visible spectrum analyzer Lambda 650S manufactured by PerkinElmer Corporation. The transmittance was measured for the range from 300 nm to 800 nm, and the value at 450 nm was recorded as the transmittance.
Permeation was measured by Mocon Permatran-W® model 3/33 at 50° C./100% RH (RH=relative humidity).

Raw Materials:

MVT-154 (vinyl phenyl silicone resin, from AB silicone company),
[Vi(CH₃)₂SiO_{1/2}]_{0.14}[(CH₃)₂SiO_{2/2}]_{0.48}[(Ph₂SiO_{2/2}]_{0.14}[PhSiO_{3/2}]_{0.24}

### Mw: 4194

VCSR-3E1 (vinyl carbosiloxane resin, Lab made),

### Mw: 6632

VCSR-3F (vinyl carbosiloxane resin, Lab made),

### Mw: 5000

M-391 (hydride phenyl silicone resin, from Kemi-works company)
[H(CH₃)₂SiO_{1/2}]_{0.38}[CH₃SiO_{3/2}]_{0.35}[PhSiO_{3/2}]_{0.27}

### Mw: 3000

KM-392 (hydride phenyl silicone chain extender, from Kemi-works company)
[H(CH₃)₂SiO_{1/2}]_{0.67}[(Ph₂SiO_{2/2}]_{0.33}

### Mw: 332

SP605 (vinyl phenyl silicone resin, from AB silicone company),
[Vi(CH₃)₂SiO_{1/2}]_{0.28}[ViCH₃SiO_{2/2}]_{0.03}[(Ph₂SiO_{2/2}]_{0.06}[CH₃SiO_{3/2}]_{0.23}[PhSiO_{3/2}]_{0.40}

### Mw: 953

VPSR (home made), [Vi(CH₃)₂SiO_{1/2}]_{0.33}[(Ph₂SiO_{2/2}]_{0.67}

### Mw: 1500

6550CV (vinyl phenyl silicone polymer, from AB silicone company)
[Vi(CH₃)₂SiO_{1/2}]_{0.12}[(CH₃)₂SiO_{2/2}]_{0.48}[(Ph₂SiO_{2/2}]_{0.40}

### Mw: 20771

XL-245PT (hydride phenyl silicone crosslinker, from AB silicone company))
[H(CH₃)₂SiO_{1/2}]_{0.75}[(PhSiO_{3/2}]_{0.25}

### Mw 330

XL-2450 (hydride phenyl silicone crosslinker, from AB silicone company))
[H(CH₃)₂SiO_{1/2}]_{0.2}[(CH₃)₂SiO_{2/2}]_{0.48}[(Ph₂SiO_{2/2}]_{0.14} [PhSiO_{3/2}]_{0.18}

### Mw 17158

SIP 6832.2 (2.0-2.3% platinum concentration in cyclic methylvinylsiloxanes, CAS: 68585-32-0, from Gelest),
3,5-Dimethyl-1-hexyn-3-ol (inhibitor, from J&K company)
Vinyl D4(1,3,5,7-Tetravinyl-1,3,5,7-tetramethylcyclotetrasiloxane, Cas 2554-06-5, from Gelest)
DVTMDS (Divinyltetramethyldisiloxane, (CAS: 2627-95-4, Mw=186.40, from Gelest)
Diphenylsilane (Cas:775-12-2, from Gelest)

### Xylene

VCSR-3E1 Synthesis:

Into a 100 ml dry and clean round bottom flask (two or three neck) was added 0.0024 g platinum catalyst SIP 6832.2, 10.34 g vinyl D4, 5.59 g DVTMDS, 9.22 g diphenylsilane and 6.28 g xylene. A magnetic stirrer was added and the flask was capped with a stopper and a condenser. The reaction was kept at 75° C. for 1 hour. Then the reaction mixture was heated up to 130° C. for 6 hours. The total solution was distilled by rotary evaporation at 115° C. and 20 mbar for 1 h, and then 135° C. and 5 mbar for another 1 h. The vinyl content of this resin is 3.0 mmol/g. Mw is 6632.

VCSR-3F Synthesis:

Into a 100 ml dry and clean round bottom flask (two or three neck) was added 0.024 g platinum catalyst SIP 6832.2, 103.2 g vinyl D4, 79.68 g KM-392. A magnetic stirrer was added and the flask was capped with a stopper and a condenser. The reaction was kept at 75° C. for 1 hour. Then the reaction mixture was heated up to 100° C. for 4 hours. The total solution was distilled by rotary evaporation at 115° C. and 20 mbar for 1 h, and then 135° C. and 5 mbar for another 1 h. The vinyl content of this resin is 3.9 mmol/g. Mw is 5000.

### APPLICATION EXAMPLES

All samples are mixed in a speedmixer at 25° C., with a mixing speed of 20-5000 rpm for 1 min-60 min.

### Application Example 1

### 443G

145.24 g MVT-154, 4.77 g KM-392, 47.57 g KM-391, 0.0176 g SIP6832.2, 0.0198 g 3,5-Dimethyl-1-hexyn-3-ol were mixed together by speedmixer, degassed, and cured at 125° C. for 1 h and 150° C. for 5 h. In addition, Si—H/Si-Vi is kept at 0.8 (Si—H/Si-Vi refers in all examples to the molar ratio of silicon bonded hydrogen atoms to silicon bonded vinyl groups present in the composition).

### Application Example 2

### 442

25.47 g MVT-154, 0.84 g VCSR-3E1, 0.88 g KM-392, 8.81 g KM-391, 0.00306 g SIP6832.2, 0.000432 g 3,5-Dimethyl-1-hexyn-3-ol were mixed together by speedmixer, degassed, and cured at 125° C. for 1 h and 150° C. for 5 h. In addition, Si—H/Si-Vi is kept at 0.8.

### Application Example 3

### 441

24.52 g MVT-154, 1.64 g VCSR-3E1, 0.89 g KM-392, 8.94 g KM-391, 0.00294 g SIP6832.2, 0.000432 g 3,5-Dimethyl-1-hexyn-3-ol were mixed together by speedmixer, degassed, and cured at 125° C. for 1 h and 150° C. for 5 h. In addition, Si—H/Si-Vi is kept at 0.8.

### Application Example 4

### 434E

129.86 g MVT-154, 13.01 g VCSR-3E1, 4.99 g KM-392, 49.72 g KM-391, 0.0155 g SIP6832.2, 0.0198 g 3,5-Dimethyl-1-hexyn-3-ol were mixed together by speedmixer, degassed, and cured at 125° C. for 1 h and 150° C. for 5 h. In addition, Si—H/Si-Vi is kept at 0.8.

### Application Example 5

### 444F

123.33 g MVT-154, 18.49 g VCSR-3E1, 5.05 g KM-392, 50.72 g KM-391, 0.0146 g SIP6832.2, 0.0198 g 3,5-Dimethyl-1-hexyn-3-ol were mixed together by speedmixer, degassed, and cured at 125° C. for 1 h and 150° C. for 5 h. In addition, Si—H/Si-Vi is kept at 0.8.

### Application Example 6

### 425H

121.74 g SP-605, 12.18 g VCSR-3E1, 25.5 g KM-392, 38.20 g KM-391, 0.0156 g SIP6832.2, 0.0198 g 3,5-Dimethyl-1-hexyn-3-ol were mixed together by speedmixer, degassed, and cured at 125° C. for 1 h and 150° C. for 5 h. In addition, Si—H/Si-Vi is kept at 0.8.

### Application Example 7

### DOE-499

31.27 g MVT-154, 3.13 g VCSR-3F, 25.01 g VPSR, 11.24 g KM-392, 0.00573 g SIP6832.2, 0.00129 g 3,5-Dimethyl-1-hexyn-3-ol were mixed together by speedmixer, degassed, and cured at 125° C. for 1 h and 150° C. for 5 h. In addition, Si—H/Si-Vi is kept at 0.8

### Application Example 8

### DOE-9

5.59 g 6550CV, 1.40 g VCSR-3E1, 2.41 g XL-2450, 0.60 g XL-245PT, 0.008 g SIP6832.2, 0.008 g 3,5-Dimethyl-1-hexyn-3-ol were mixed together by speedmixer, degassed, and cured at 150° C. for 2 h. In addition, Si—H/Si-Vi is kept at 2.

### Application Example 9

### DOE-6

1.66 g 6550CV, 3.52 g VCSR-3E1, 3.28 g XL-2450, 1.54 g XL-245PT, 0.008 g SIP6832.2, 0.008 g 3,5-Dimethyl-1-hexyn-3-ol were mixed together by speedmixer, degassed, and cured at 150° C. for 2 h. In addition, Si—H/Si-Vi is kept at 2.

### Application Example 10

### DOE-4

1.89 g 6550CV, 4.01 g VCSR-3E1, 2.79 g XL-2450, 1.31 g XL-245PT, 0.008 g SIP6832.2, 0.008 g 3,5-Dimethyl-1-hexyn-3-ol were mixed together by speedmixer, degassed, and cured at 150° C. for 2 h. In addition, Si—H/Si-Vi is kept at 1.50.

### Application Example 11

### DOE-5

2.21 g 6550CV, 4.69 g VCSR-3E1, 0.62 g XL-2450, 2.48 g XL-245PT, 0.008 g SIP6832.2, 0.008 g 3,5-Dimethyl-1-hexyn-3-ol were mixed together by speedmixer, degassed, and cured at 150° C. for 2 h. In addition, Si—H/Si-Vi is kept at 1.50.

### Comparative Application Example

100 g Dow Corning 6636 (high RI) LED encapsulant Part A, 200 g Dow Corning 6636 (high RI) LED encapsulant Part B were mixed together by speedmixer, degassed, and cured at 150° C. for 2 h.

TABLE 1

| | Application | Application | Application |
|---|---|---|---|
| Item | Example 1 | Example 2 | Example 3 |
| VCSR % | 0% | 2.3% | 4.6% |
| Barrier property | 80 | 79 | 80 |
| g · mil/100 inch² · day | | | |
| (50° C.) | | | |
| T %@400 nm | 89% | 89% | 89% |
| (initial) | | | |
| T %@400 nm | 80% | 81% | 88% |
| (15° C., 1000 hours) | | | |
| T %@400 nm | 76% | 74% | 77% |
| (175° C., 1000 hours) | | | |

TABLE 2

| | Application | Application | Application |
|---|---|---|---|
| Item | Example 4 | Example 5 | Example 6 |
| VCSR % | 6.6% | 9.4% | 4.4% |
| Barrier property | 75 | 79 | 80 |
| g · mil/100 inch² · day | | | |
| (50° C.) | | | |
| T %@400 nm | 89% | 89% | 89% |
| (initial) | | | |
| T %@400 nm | 88% | 88% | 88% |
| (15° C., 1000 hours) | | | |
| T %@400 nm | 81% | 82% | 84% |
| (175° C., 1000 hours) | | | |

TABLE 3

| | Application | Application | Application |
|---|---|---|---|
| Item | Example 7 | Example 8 | Example 9 |
| VCSR % | 6.6% | 14.0% | 35.2% |
| Barrier property | 66 | 80 | 80 |
| g · mil/100 inch² · day | | | |
| (50° C.) | | | |
| T %@400 nm | 89% | 89% | 89% |
| (initial) | | | |
| T %@400 nm | 88% | 88% | 85% |
| (15° C., 1000 hours) | (300 h) | | |
| T %@400 nm | 81% | 86% | 83% |
| (175° C., 1000 hours) | | | |

TABLE 4

| | | | Comparative |
|---|---|---|---|
| | Application | Application | application |
| Item | Example 10 | Example 11 | example |
| VCSR % | 40.1% | 46.9% | N/A |
| Barrier property | 78 | 79 | 80 |
| g · mil/100 inch² · day | | | |
| (50° C.) | | | |
| T %@400 nm | 89% | 89% | 89% |
| (initial) | | | |
| T %@400 nm | 88% | 87% | 84% |
| (15° C., 1000 hours) | | | |
| T %@400 nm | 85% | 82% | 64% |
| (175° C., 1000 hours) | | | |

As can be seen from the results given, cured products according to the invention show improved thermal stabilities behavior compared to cured products obtained from commercially available encapsulating materials based on organopolysiloxanes. Besides, permeation behaviors, i.e. barrier properties are similar.

What is claimed is:

1. A curable composition, comprising:
(A) at least one organopolysiloxane A represented by the following formula (1):
[R¹R²R³SiO_{1/2}]_{M}[R⁴R⁵SiO_{2/2}]_{D}[R⁶SiO_{3/2}]_{T}[SiO_{4/2}]_{Q},
wherein R¹, R², R³, R⁴, R⁵, and R⁶, each independently designates a methyl group, an ethyl group, a vinyl group, a phenyl group, with the proviso that each molecule comprises at least 2 vinyl groups directly bonded to silicon; and M, D, T, and Q each represents a number ranging from 0 to less than 1, provided that M+D+T+Q is 1, and
(B) at least one organopolysiloxane B represented by the following formula (2):
[R⁷R⁸R⁹SiO_{1/2}]_{M′}[R¹⁰R¹¹SiO_{2/2}]_{D′}[R¹²SiO_{3/2}]_{T′}[SiO_{4/2}]_{Q′}, (2),
wherein R⁷, R⁸, R⁹, R¹⁰, R¹¹, and R¹², each independently designates a methyl group, an ethyl group, a phenyl group, or hydrogen, with the proviso that each molecule comprises at least 2 phenyl groups and 2 hydrogen atoms directly bonded to silicon, and M′, D′, T′, and Q′ each represents a number ranging from 0 to less than 1, provided that M′+D′+T′+Q′ is 1,
(C) at least one vinyl carbosiloxane polymer comprising the structures 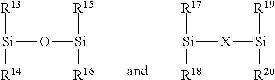
within each molecule, wherein R¹³, R¹⁴, R¹⁵, R¹⁶ R¹⁷, R¹⁸ R¹⁹, and R²⁰ each independently designates a methyl group, an ethyl group, a vinyl group, or a phenyl group, with the proviso that each molecule comprises at least 2 vinyl groups and at least one phenyl group directly bonded to silicon, and X is ethylene or arylene, and
(D) at least a catalyst.

2. The curable composition according to claim 1, comprising an organopolysiloxane A represented by the formula (1), wherein M is greater than 0.

3. The curable composition according to claim 1, wherein the weight average molecular weight of the organopolysiloxane A is from 300 g/mol to 300,000 g/mol, preferably from 1000 g/mol to 100,000 g/mol.

4. The curable composition according to claim 1, comprising an organopolysiloxane B represented by the formula (2), wherein M′ is greater than 0.

5. The curable composition according to claim 1, wherein organopolysiloxane A, organopolysiloxane B and the vinyl carbosiloxane polymer are present in respective amounts to provide a molar Si—H/Si-Vinyl ratio of from 0.5 to 10, preferably from 0.6 to 5.

6. The curable composition according to claim 1, wherein the weight average molecular weight of the organopolysiloxane B is from 500 g/mol to 300,000 g/mol, preferably from 600 g/mol to 100,000 g/mol.

7. The curable composition according to claim 1, wherein the vinyl carbosiloxane polymer is the hydrosilylation reaction product of 1,3,5,7-tetravinyl-1,3,5,7-tetramethylcyclotetrasiloxane and at least one hydride-terminated linear polysiloxane, siloxane, carbosilane or silane, having two terminal Si—H hydrogens reactive with vinyl groups in a hydrosilylation reaction, wherein at least one of the hydride-terminated linear polysiloxanes, siloxanes, carbosilanes or silanes comprises at least one phenyl group directly bonded to a silicon atom.

8. The curable composition according to claim 7, wherein the hydride-terminated linear polysiloxane, siloxane, carbosilane or silane, having two terminal Si—H hydrogens reactive with vinyl groups in a hydrosilylation reaction is selected from those having the structures: 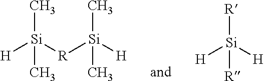
wherein R is a arylene group, a linear silicone unit of the structure —(O—SiAr₂)—ₙ or —(O—SiMeAr)—ₙ in which n is an integer from 1 to 1000 and represents the number of repeating units; Me is a methyl group; Ar is an aryl group; and R′ and R″ independently are a C1 to C4 alkyl group or an aryl group with the proviso that at least one of R′ and R″ is phenyl.

9. The curable composition according to claim 7, wherein the hydrosilylation reaction of one or more of the vinyl groups of 1,3,5,7-tetravinyl-1,3,5,7-tetramethylcyclotetrasiloxane with a Si—H hydrogen of the hydride-terminated linear polysiloxane, siloxane, carbosilane or silane is performed under Pt catalysis at 70-150° C. for 1-10 hours.

10. The curable composition according to claim 1, wherein the molecular weight of the vinyl carbosiloxane polymer is from 500 to 100,000 g/mol, preferably from 1500 to 50,000 g/mol.

11. The curable composition according to claim 1, wherein the catalyst is a platinum group metal catalyst.

12. The curable composition according to claim 1, wherein the catalyst is present in such an amount that the content of the catalytic metal is in the range of 1 to 500 ppm, preferably 2 to 100 ppm, based on the total weight of the curable composition.

13. A cured product obtainable by heating a curable composition according to claim 1.

14. Use of the composition according to claim 1 as semiconductor encapsulating material and/or electronic elements packaging material.
